(19) United States
(12) Patent Application Publication
(10) Pub. No.: US 2025/0338530 A1
(43) Pub. Date: Oct. 30, 2025

(54) SEMICONDUCTOR STRUCTURE AND METHOD FOR FORMING THE SAME

(71) Applicant: Semiconductor Manufacturing International (Shanghai) Corporation, Shanghai (CN)

(72) Inventors: Jaewoo KIM, Shanghai (CN); Byungsup SHIM, Shanghai (CN); Saiya ZHU, Shanghai (CN)

(21) Appl. No.: 19/191,780

(22) Filed: Apr. 28, 2025

(30) Foreign Application Priority Data
Apr. 29, 2024 (CN) 202410535793.0

(51) Int. Cl. H10D 30/01; H10D 30/00

(52) U.S. Cl. CPC H10D 30/0193; H10D 30/501

(57) ABSTRACT

A semiconductor structure and a method for forming the same, where the semiconductor structure includes a substrate; a channel layer structure suspended above the substrate, where in the vertical direction, the channel layer structure includes one or more spaced channel layers; a repair layer covering the surfaces of the channel layers; and a gate structure located on the substrate and spanning the channel layer structure, where the gate structure surrounds the channel layers along the extension direction of the gate structure and covers the repair layer.

### CROSS-REFERENCE TO RELATED APPLICATION

This application claims priority to Chinese Patent Application No. 202410535793.0, filed on Apr. 29, 2024, the content of which is incorporated herein by reference in its entirety.

### TECHNICAL FIELD

The application generally relates to the field of semiconductor manufacturing, and in particular to a semiconductor structure and a method for forming the same.

### BACKGROUND

In semiconductor manufacturing, with the development trend of ultra-large-scale integrated circuits, the feature size of integrated circuits continues to shrink. In order to accommodate smaller feature sizes, the channel length of metal-oxide-semiconductor field-effect transistors (MOSFETs) has also been shortened accordingly. However, as the channel length of the device shortens, the distance between the source and drain of the device also shortens, so the gate structure's ability to control the channel becomes worse, and it becomes increasingly difficult for the gate voltage to pinch off the channel, making the phenomenon of subthreshold leakage, the so-called short-channel effects (SCE), more likely to occur.

Therefore, in order to better meet the requirements of device size miniaturization, semiconductor processes have gradually begun to transition from planar transistors to more efficient three-dimensional transistors, such as gate-all-around (GAA) transistors. In a metal-all-around transistor, the gate surrounds the channel area from all sides. Compared with planar transistors, the gate of a metal-all-around transistor has stronger control over the channel and may better suppress the short channel effects.

### SUMMARY

The problem solved by the embodiments of the present disclosure is to provide a semiconductor structure and a method for forming the same, which are beneficial to improving the working performance of the semiconductor structure.

To solve the above problems, an embodiment of the present disclosure provides a semiconductor structure, including: a substrate; a channel layer structure suspended above the substrate, where, in a vertical direction, the channel layer structure includes one or more spaced channel layers; a repair layer, covering surfaces of the channel layers; and a gate structure located on the substrate and across the channel layer structure, where the gate structure surrounds the channel layers along an extension direction of the gate structure and covers the repair layer.

Optionally, the repair layer covers upper and lower surfaces of the channel layers.

Optionally, the semiconductor structure further includes an isolation layer located between the channel layer structure and the substrate, where in the channel layer structure, a bottom channel layer is in contact with the isolation layer; and the repair layer covers an upper surface of the bottom channel layer.

Optionally, the semiconductor structure further includes a source-drain doped layer, located on the substrate at both sides of the gate structure, and in an extension direction of the channel layer structure, the source-drain doped layer is in contact with side surfaces of the channel layer structure; and the isolation layer is also located between the source-drain doped layer and the substrate.

Optionally, the semiconductor structure further includes inner sidewalls located between adjacent channel layers and between the gate structure and the source-drain doped layer, where the repair layer is disposed on surfaces of the channel layers exposed by the inner sidewalls.

Optionally, a material of the repair layer includes silicon germanium.

Optionally, a thickness of the repair layer is less than or equal to 2 nm.

Optionally, a material of the channel layers includes silicon, germanium, silicon germanium, or a group III-V semiconductor material.

Optionally, the gate structure includes a gate dielectric layer surrounding a channel layer along the extension direction of the gate structure and a gate electrode layer located on the gate dielectric layer, where the gate electrode layer includes a work function layer and an electrode layer located on the work function layer.

Correspondingly, an embodiment of the present disclosure also provides a method for forming a semiconductor structure, including: providing a substrate; forming a channel layer structure suspended above the substrate, where the channel layer structure includes one or more spaced channel layers in a vertical direction, forming a repair layer covering surfaces of the channel layers; and forming a gate structure on the substrate and across the channel layer structure, where the gate structure surrounds the channel layers along an extension direction of the gate structure and covers the repair layer.

Optionally, in a process of forming the repair layer covering the surfaces of the channel layers, the repair layer covers upper and lower surfaces of the channel layers.

Optionally, in a process of providing the substrate, an isolation layer is formed on the substrate; in a process of forming the channel layer structure suspended above the substrate, a bottom channel layer is in contact with the isolation layer; and in a process of forming the repair layer covering the surfaces of the channel layers, the repair layer covers a upper surface of the bottom channel layer.

Optionally, in the process of providing the substrate, a stacked structure is formed on the isolation layer, the stacked structure including alternately stacked channel layers and sacrificial layers, where a bottom layer of the stacked structure is a channel layer; in the process of forming the channel layer structure suspended above the substrate, the sacrificial layers are removed to form grooves exposing the surfaces of the channel layers, where a plurality of spaced channel layers constitute the channel layer structure; and in the process of forming the repair layer covering the surfaces of the channel layers, the repair layer is formed on the surfaces of the channel layers through the grooves.

Optionally, in the process of providing the substrate, a source-drain doped layer is formed on the isolation layer on both sides of the stacked structure along an extension direction of the stacked structure, and the source-drain doped layer is in contact with side surfaces of the stacked structure.

Optionally, in the process of providing the substrate, inner sidewalls are further formed between the sacrificial layers and the source-drain doped layer; in a process of removing the sacrificial layers, the grooves also expose the inner sidewalls; and in the process of forming the repair layer covering the surfaces of the channel layers, the repair layer is formed on surfaces of the channel layers exposed by the inner sidewalls.

Optionally, in the process of forming the gate structure across the channel layer structure on the substrate, the gate structure fills the grooves and covers the repair layer.

Optionally, an epitaxial growth process is used to form the repair layer covering the surfaces of the channel layers.

Optionally, in the process of forming the repair layer covering the surfaces of the channel layers, a material of the repair layer includes silicon germanium.

Optionally, in the process of forming the repair layer covering the surfaces of the channel layers, a thickness of the repair layer is less than or equal to 2 nm.

Optionally, in the process of forming the channel layer structure suspended above the substrate, a material of the channel layers includes silicon, germanium, silicon germanium, or a group III-V semiconductor material.

It should be understood that the above summary and the following detailed description are merely exemplary and explanatory, and are not intended to limit the technical solutions of the present disclosure. Other features of the present disclosure and advantages thereof will become apparent from the following detailed description of exemplary embodiments of the present disclosure with reference to the accompanying drawings.

### BRIEF DESCRIPTION OF THE DRAWINGS

In order to more clearly illustrate the technical solutions in the embodiments of the disclosure, the drawings essential for understanding the disclosed embodiments will be briefly described below. Apparently, the drawings described below are merely some embodiments of the disclosure. For a person skilled in the art, other drawings may be obtained based on the provided drawings without making creative efforts.

FIGS. 1 and 2 are schematic structural diagrams corresponding to various steps in a method for forming a semiconductor structure;

FIGS. 3 and 4 are schematic structural diagrams of a semiconductor structure, according to an embodiment of the present disclosure; and

FIGS. 5 to 9 are schematic structural diagrams corresponding to various steps in another method for forming a semiconductor structure, according to an embodiment of the present disclosure.

### DETAILED DESCRIPTION

In order to make the objective, technical solutions, and advantages of the present disclosure clearer, the technical solutions of the present disclosure are further elaborated in detail hereinafter in conjunction with the accompanying drawings and specific embodiments. The described embodiments should not be regarded as limiting the present disclosure. All other embodiments obtained by a person skilled in the art without making creative efforts still fall within the scope of protection of the present disclosure.

In the following descriptions, reference is made to “some embodiments”, which describe a subset of all possible embodiments, but it is understood that “some embodiments” may be the same subset or different subsets of all possible embodiments, and may be combined with each other without conflict. The terms “first/second/third” are merely used to distinguish similar objects and do not indicate a specific order for the objects. It is understood that “first/second/third” may be interchanged in a specific order or sequence where permitted, so that the embodiments of the present disclosure described herein may be implemented in an order other than those illustrated or described herein.

Unless otherwise defined, technical and scientific terms used herein have the same meaning as those commonly understood by those skilled in the art to which the present disclosure belongs. The terms used herein are merely for the purpose of describing the present disclosure and are not intended to limit the disclosure.

In the existing technologies, the working performance of semiconductor structures needs to be improved. The reasons why the working performance needs to be improved are illustrated in combination with a method for forming a semiconductor structure.

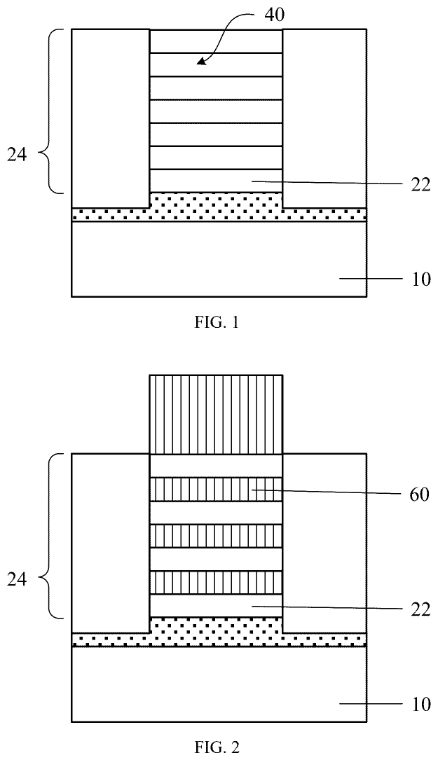

FIGS. 1 to 2 are schematic structural diagrams corresponding to various steps in a method for forming a semiconductor structure.

Referring to FIG. 1, a substrate 10 is provided, on which a stacked structure is formed, where the stacked structure includes multiple channel layers 22 and sacrificial layers alternately stacked in the vertical direction (i.e., a direction perpendicular to the substrate 10). The sacrificial layers are then removed to form grooves 40 located between adjacent channel layers 22, where the multiple channel layers 22 spaced apart in the vertical direction are retained as a channel layer structure 24.

Referring to FIG. 2, a gate structure is formed across the channel layer structure 24 and filled in the grooves 40 surrounding the channel layers 22.

In the semiconductor manufacturing process, the surfaces of the channel layers 22 are prone to damage and defects. Especially after the process of removing the sacrificial layers, the exposed surfaces of the channel layers 22 are easily damaged, resulting in poor surface quality of the channel layers 22 and surface defects. After the gate structure is formed, the gate structure surrounds the channel layers 22, and the surface quality of the channel layers 22 is poor. That is, the surface quality of the channel surface in contact between the gate structure and the channel layers 22 is poor, thereby affecting the mobility of the channel layers 22 and affecting the working performance of the semiconductor structure.

In order to solve this technical problem and other problems in the existing semiconductor manufacturing processes, embodiments of the present disclosure provide a semiconductor structure, including a substrate; a channel layer structure suspended above the substrate, where in the vertical direction, the channel layer structure includes one or more spaced channel layers; a repair layer covering the surfaces of the channel layers; and a gate structure located on the substrate and spanning the channel layer structure, where the gate structure surrounds the channel layers along an extension direction of the gate structure and covers the repair layer.

In the semiconductor structure provided by the embodiments of the present disclosure, the repair layer covers the surfaces of the channel layers, the gate structure is located on the substrate and spans the channel layer structure, and the gate structure surrounds the channel layers along the extension direction of the gate structure and covers the repair layer. In the embodiments of the present disclosure, the repair layer covers the surfaces of the channel layers, which helps ameliorate the defects on the surfaces of the channel layers to obtain a channel surface with higher surface quality. The gate structure surrounds the channel layers and covers the repair layer. The repair layer is used as the channel surface to contact the gate structure, so that the surface quality of the channel surface in contact between the gate structure and the channel layers is improved, which helps improve the mobility of the channel layers, thereby improving the working performance of the semiconductor structure.

In order to make the objective, features, and advantages of the present disclosure clearer and easier to understand, specific embodiments of the present disclosure are described in detail hereinafter with reference to the accompanying drawings.

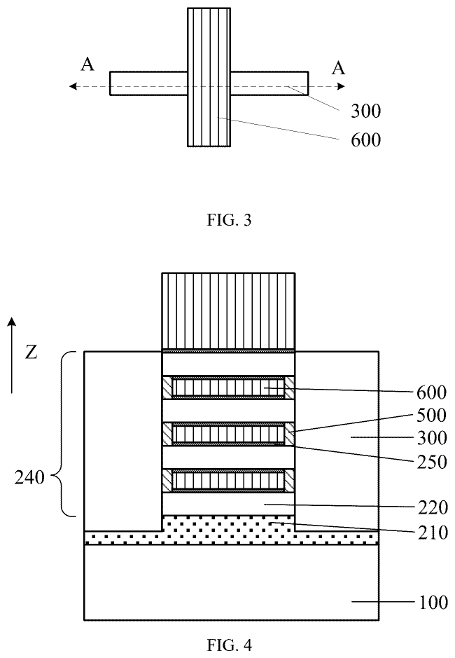

FIGS. 3 and 4 are schematic diagrams of structures of a semiconductor structure according to an embodiment of the present disclosure. FIG. 3 is a top view of a gate structure and a source-drain doped layer, and FIG. 4 is a cross-sectional view of FIG. 3 based on the AA direction.

With reference to FIGS. 3 and 4, the semiconductor structure includes a substrate 100; a channel layer structure 200 suspended above the substrate 100, and in the vertical direction (shown as the Z direction in FIG. 4), the channel layer structure 200 includes one or more spaced channel layers 220; a repair layer 250 covering the surfaces of the channel layers 220 (e.g., covering upper and lower surfaces of each channel layer except the upper surface of the top channel layer and the lower surface of the bottom channel layer); a gate structure 600 located on the substrate 100 and spanning the channel layer structure 240, where the gate structure 600 surrounds the channel layers 220 along the extension direction of the gate structure 600 and covers the repair layer 250.

The substrate 100 provides a process operation basis for the formation process of the semiconductor structure, where the semiconductor structure includes a gate-all-around (GAA) transistor and a forksheet transistor.

In some embodiments, the material of the substrate 100 is silicon. In some embodiments, the material of the substrate may also be other materials such as germanium, silicon germanium, silicon carbide, gallium arsenide, indium gallium, etc. In some embodiments, the substrate may also be other types of substrates such as silicon on insulator substrates or germanium on insulator substrates. The material of the substrate may be a material suitable for process requirements or easy to integrate.

In some embodiments, the semiconductor structure further includes an isolation layer 210 located between the channel layer structure 240 and the substrate 100.

The isolation layer 210 is used to isolate the gate structure 600 from the substrate 100, and isolate the channel layer structure 240 from the substrate 100.

The bottom of the gate structure 600 and the substrate 100 are isolated by the isolation layer 210, and the isolation layer 210 effectively isolates the contact between the gate structure 600 and the substrate 100, thereby reducing the probability of current leakage between the gate structure 600 and the substrate 100. At the same time, the isolation layer 210 effectively isolates the contact between the channel layers 220 and the substrate 100. When the channel layers 220 are turned on, the parasitic capacitance of the substrate 100 is reduced or prevented to increase due to the turning on of the channel layers 220.

In some embodiments, the material of the isolation layer 210 includes a dielectric material, which may isolate the gate structure 600 and the substrate 100, as well as the channel layer structure 240 and the substrate 100. Moreover, the dielectric material has high process compatibility, thereby reducing the impact of the isolation layer 210 on the process.

In some embodiments, the material of the isolation layer 210 includes SiN, SiON, SiOCN, SiOC, SiOCH, etc. The k value of SiN, SiON, SiOCN, SiOC, SiOCH, etc., is relatively small, which facilitates isolating the gate structure 600 from the substrate 100, and isolating the channel layer structure 240 from the substrate 100, thereby reducing the parasitic capacitance between the gate structure 600 and the substrate 100.

The channel layer structure 200 includes one or more channel layers 220 spaced apart in the vertical direction, and a channel layer 220 is used as a channel of a transistor.

In some embodiments, the material of the channel layers 220 includes silicon, germanium, silicon germanium, III-V semiconductor materials, etc. As an example, the material of the channel layers 220 is silicon. In some embodiments, the material of the channel layers is determined according to the type and performance of the transistor.

In some embodiments, in the channel layer structure 240, the bottom channel layer 220 is in contact with the isolation layer 210.

In the channel layer structure 240, the bottom channel layer 220 is in contact with the isolation layer 210, so the bottom channel layer 220 is isolated from the substrate 100 by the isolation layer 210.

The repair layer 250 is used to repair the surfaces of the channel layers 220 to obtain a channel surface with better surface quality.

In some embodiments, the repair layer 250 covers the surfaces of the channel layers 220, which is beneficial to ameliorating the defects on the surfaces of the channel layers 220 and obtaining a channel surface with higher surface quality. The gate structure 600 surrounds the channel layers 220 and covers the repair layer 250. The repair layer 250 is used as the channel surface to contact the gate structure 600, so that the surface quality of the channel surface in contact between the gate structure 600 and the channel layers 220 is improved, which is beneficial to improving the mobility of the channel layers 220, thereby helping improve the working performance of the semiconductor structure.

In some embodiments, the repair layer 250 covers the upper and lower surfaces of the channel layers 220 (except the upper surface of the top channel layer and the lower surface of the bottom channel layer).

The repair layer 250 covers the surfaces on the upper and lower surfaces of the channel layers 220, and may repair the exposed surfaces of the channel layers 220, so that each surface of the channel layers 220 has a good surface quality, thereby making each channel surface in contact between the gate structure 600 and the channel layers 220 have an improved surface quality, which facilitates improving the mobility of the channel layer 220, and further improving the working performance of the semiconductor structure.

In some embodiments, in the channel layer structure 240, the bottom channel layer 220 is in contact with the isolation layer 210, and accordingly, the repair layer 250 covers the upper surface of the bottom channel layer 220.

In some embodiments, the material of the repair layer 250 includes silicon germanium or other similar materials.

The silicon germanium-covered channel layers 220 serve as the channel surface, which may provide better mobility for the channels. Moreover, the material of the channel layers 220 is silicon, and the repair layer 250 uses silicon germanium. The repair layer 250 may be formed on the surfaces of the channel layers 220 by an epitaxial growth process. The formation process is simple and does not require an additional etching process, thereby minimizing damage to the structure.

In addition, the epitaxial growth process may better control the process parameters, and the process controllability is high, and it is easy to obtain a more precise film thickness of the repair layer 250. The epitaxial growth process makes it easy to form a film layer with fewer impurities, so that the film quality of the repair layer 250 is higher, which is further beneficial to ameliorate the defects on the surface of a channel layer 220 and obtain a channel surface with higher surface quality. Correspondingly, the surface quality of the channel surface in contact between the gate structure 600 and the channel layers 220 is improved, which is further beneficial to improve the mobility of the channel layers 220, and thus is more beneficial to improve the working performance of the semiconductor structure.

It should be noted that, in the disclosed embodiments, the thickness of the repair layer 250 should not be too large. If the thickness of the repair layer 250 is too large, it is easy to cause the repair layer 250 to occupy too much space between the adjacent channel layers 220 in the vertical direction, thereby resulting in insufficient space between the adjacent channel layers 220 in the vertical direction for forming the gate structure 600. This is easy to cause difficulties in the formation of the gate structure 600, and also affects the formation quality of the gate structure 600, thereby affecting the working performance of the semiconductor structure. For this reason, in the disclosed embodiments, the thickness of the repair layer 250 is less than or equal to 2 nm.

The gate structure 600 is used to control the turning on and off of a channel of a transistor.

The gate structure 600 surrounds and covers the channel layers 220, so the top, bottom, and sidewalls of the channel layers 220 may all serve as channels, increasing the area of the channel layers 220 used as a channel, thereby increasing the operating current of the semiconductor structure.

In some embodiments, the gate structure 600 includes a gate dielectric layer surrounding the channel layers 220 along the extension direction of the gate structure 600, and a gate electrode layer located on the gate dielectric layer.

The gate dielectric layer is used to isolate the gate electrode layer from the channel layers 220, and isolate the gate electrode layer from the substrate 100.

The material of the gate dielectric layer includes one or more of HfO₂, ZrO₂, HfSiO, HfSiON, HfTaO, HfTiO, HfZrO, Al₂O₃, SiO₂, La₂O₃, etc. In some embodiments, the gate dielectric layer includes a high-k gate dielectric layer, and the material of the high-k gate dielectric layer includes a high-k dielectric material. The high-k dielectric material refers to a dielectric material having a relative dielectric constant greater than the relative dielectric constant of silicon oxide. Specifically, the material of the high-k gate dielectric layer includes HfO₂, ZrO₂, HfSiO, HfSiON, HfTaO, HfTiO, HfZrO, Al₂O₃, etc.

It should be noted that the gate dielectric layer may further include a gate oxide layer, and the gate oxide layer is located between the high-k gate dielectric layer and the channel layer 220. Specifically, the material of the gate oxide layer may be silicon oxide.

In some embodiments, the gate structure 600 is a metal gate structure. In some embodiments, the material of the gate electrode layer includes one or more of TiN, TaN, Ta, Ti, TiAl, W, Al, TiSiN, TiAlC, etc.

Specifically, the gate electrode layer includes a work function layer (not shown) and an electrode layer (not shown) located on the work function layer, where the work function layer is used to adjust the threshold voltage of the transistor, and the electrode layer is used to lead out the electrical properties of the metal gate structure.

In some embodiments, the gate electrode layer may also only include a work function layer.

In some embodiments, according to process requirements, the gate structure may also be a polysilicon gate structure.

In some embodiments, the semiconductor structure further includes a source-drain doped layer 300 located on the substrate 100 on both sides of the gate structure 600, and the source-drain doped layer 300 is in contact with sides of the channel layer structure 240 in the extension direction of the channel layer structure 240.

The source-drain doped layer 300 is used as a source region or a drain region of a transistor. Specifically, the doping type of the source-drain doped layer 300 is the same as the channel conductivity type of the corresponding transistor.

The doping type of the source-drain doped layer 300 is the same as the channel conductivity type of the corresponding transistor. Specifically, when the substrate 100 is used to form an NMOS transistor, the doped ions in the source-drain doped layer 300 are N-type ions, and the N-type ions include P ions, As ions, Sb ions, etc. When the substrate 101 is used to form a PMOS transistor, the doped ions in the source-drain doped layer 300 are P-type ions, and the P-type ions include B ions, Ga ions, In ions, etc.

In some embodiments, the isolation layer 210 is also located between the source-drain doped layer 300 and the substrate 100.

The isolation layer 210 also extends between the bottom of the source-drain doped layer 300 and the top of the substrate 100, thereby facilitating the reduction of leakage of the source-drain doped layer 300 and the parasitic capacitance between the source-drain doped layer 300 and the substrate 100.

In some embodiments, the semiconductor structure further includes inner sidewalls 500 located between adjacent channel layers 220 and between the gate structure 600 and the source-drain doped layer 300.

The inner sidewalls 500 serve to isolate the gate structure 600 from the source-drain doped layer 300, so as to reduce the parasitic capacitance between the gate structure 600 and the source-drain doped layer 300.

In some embodiments, the material of the inner sidewalls 500 includes a dielectric material, and the dielectric material may play a role of optimal isolation between the gate structure 600 and the source-drain doped layer 300.

Specifically, in the disclosed embodiments, the material of the inner sidewalls 500 includes SiN, SiON, SiOCN, SiOC, SiOCH, etc. The k value of SiN, SiON, SiOCN, SiOC, SiOCH, etc., is relatively small, which is more conducive to isolating the gate structure 600 and the source-drain doped layer 300, thereby reducing the parasitic capacitance between the gate structure 600 and the source-drain doped layer 300.

It should be noted that, in the present disclosure, in the semiconductor structure manufacturing process, after forming the inner sidewalls 500 located between the vertically adjacent channel layers 220, a repair layer 250 covering the surfaces of the channel layers 220 is formed. Accordingly, in the present disclosure, the repair layer 250 is located on the surfaces of the channel layers 220 exposed by the inner sidewalls 500.

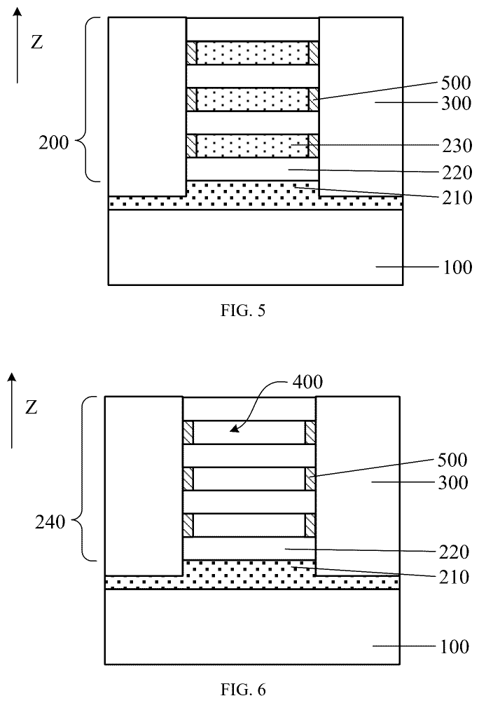

FIGS. 5 to 9 are schematic structural diagrams corresponding to the steps of a method for forming a semiconductor structure, according to some embodiments of the present disclosure.

Referring to FIG. 5, a substrate 100 is provided.

The substrate 100 provides a process operation basis for the formation process of the semiconductor structure, where the semiconductor structure includes a GAA transistor and a fork-shaped gate transistor.

In some embodiments, the material of the substrate 100 is silicon. In some embodiments, the material of the substrate may also be other materials such as germanium, silicon germanium, silicon carbide, gallium arsenide, indium gallium, etc. In some embodiments, the substrate may also be other types of substrates, such as silicon on insulator substrates, germanium on insulator substrates, etc. The material of the substrate may be a material suitable for process requirements or easy to integrate.

In some embodiments, in the process of providing the substrate 100, an isolation layer 210 is formed on the substrate 100.

The isolation layer 210 is used to isolate the subsequently formed gate structure from the substrate 100, and the subsequently formed channel layer structure from the substrate 100.

The bottom of the gate structure and the substrate 100 are isolated by the isolation layer 210, and the isolation layer 210 effectively isolates the contact between the gate structure and the substrate 100, thereby reducing the probability of current leakage between the gate structure and the substrate 100. At the same time, the isolation layer 210 effectively isolates the contact between a channel layer (e.g., the bottom channel layer) and the substrate 100. When the channel layer is turned on, the parasitic capacitance of the substrate 100 is reduced or prevented to increase due to the turning on of the channel layer.

In some embodiments, the material of the isolation layer 210 includes a dielectric material, which may isolate the gate structure and the substrate 100, as well as the channel layer structure and the substrate 100. Moreover, the dielectric material has high process compatibility, thereby reducing the impact of the isolation layer 210 on the process.

In some embodiments, the material of the isolation layer 210 includes SiN, SiON, SiOCN, SiOC, SiOCH, etc. The k value of SiN, SiON, SiOCN, SiOC, SiOCH, etc., is relatively small, which is more conducive to isolating the gate structure from the substrate 100, and isolating the channel layer structure from the substrate 100, thereby reducing the parasitic capacitance between the gate structure and the substrate 100.

In some embodiments, in the process of providing the substrate 100, a stacked structure is formed on the isolation layer 210. The stacked structure includes alternately stacked channel layers 220 and sacrificial layers 230, where the bottom layer of the stacked structure is a channel layer 220.

A channel layer 220 in the stacked structure is used as a channel of the semiconductor structure, and a sacrificial layer 230 is used to provide a process basis for the subsequent suspended arrangement of the channel layer 220, and is also used to occupy a space for the gate structure formed subsequently. In the subsequent process, the sacrificial layers 230 are removed, so that the channel layers 220 are suspended, and the gate structure is formed between the bottom channel layer 220 and the substrate 100 and between adjacent channel layers 220.

The surface of a channel layer 220 covered by the gate structure is used as a channel. In some embodiments, the top, bottom, and sidewalls of a channel layer 220 may all be used as channels, increasing the area of the channel layer 220 used as a channel, thereby increasing the operating current of the semiconductor structure.

In some embodiments, the bottom layer of the stacked structure is the channel layer 220. In the stacked structure, the bottom channel layer 220 is in contact with the isolation layer 210, so the bottom channel layer 220 is isolated from the substrate 100 by the isolation layer 210.

In some embodiments, in the process of providing the substrate 100, the material used for the channel layers 220 includes silicon, germanium, silicon germanium, III-V semiconductor materials, etc. As an example, the material of the channel layers 220 is silicon. In some embodiments, the material of the channel layers is determined according to the type and performance of a transistor.

In some embodiments, in the process of providing the substrate 100, the material used for the sacrificial layers 230 includes silicon germanium.

The etching resistance of silicon germanium is lower than that of silicon, and silicon germanium may form a larger etching selectivity ratio with silicon. Therefore, in the subsequent process of removing the sacrificial layers 230, the sacrificial layers 230 are easy to remove and the damage to the channel layers 220 may be reduced when removing the sacrificial layers 230.

In some embodiments, a second sacrificial layer may be made of a suitable material having an etching selectivity ratio compatible with the channel layers according to the material of the channel layers, so as to reduce damage to the channel layers when the second sacrificial layer is subsequently removed.

In some embodiments, in the process of providing the substrate 100, a source-drain doped layer 300 is formed on the isolation layers 210 on both sides of the stacked structure along the extension direction of the stacked structure, and the source-drain doped layer 300 is in contact with the side surfaces of the stacked structure.

The source-drain doped layer 300 is used as a source region or a drain region of the transistor. Specifically, the doping type of the source-drain doped layer 300 is the same as the channel conductivity type of the corresponding transistor.

The doping type of the source-drain doped layer 300 is the same as the channel conductivity type of the corresponding transistor. Specifically, when the substrate 100 is used to form an NMOS transistor, the doped ions in the source-drain doped layer 300 are N-type ions, and the N-type ions include P ions, As ions, Sb ions, etc. When the substrate 101 is used to form a PMOS transistor, the doped ions in the source-drain doped layer 300 are P-type ions, and the P-type ions include B ions, Ga ions, In ions, etc.

In some embodiments, in the process of providing the substrate 100, the isolation layer 210 is also disposed between the source-drain doped layer 300 and the substrate 100.

The isolation layer 210 also extends between the bottom of the source-drain doped layer 300 and the top surface of the substrate 100, thereby facilitating the reduction of leakage and the parasitic capacitance between the source-drain doped layer 300 and the substrate 100.

In some embodiments, in the process of providing the substrate 100, inner sidewalls 500 are further formed between the sacrificial layers 230 and the source/drain doped layer 300.

The inner sidewalls 500 are used to isolate the gate structure and the source-drain doped layer 300 to be formed subsequently, so as to reduce the parasitic capacitance between the gate structure and the source-drain doped layer 300.

In some embodiments, in the process of providing the substrate 100, the material of the inner sidewalls 500 includes a dielectric material, and the dielectric material may play a role in optimal isolation between the gate structure and the source-drain doped layer 300 to be formed subsequently.

Specifically, in the disclosed embodiments, the material of the inner sidewalls 500 includes SiN, SiON, SiOCN, SiOC, SiOCH, etc. The k value of SiN, SiON, SiOCN, SiOC, SiOCH, etc., is smaller, which is more conducive to isolating the subsequently formed gate structure and the source-drain doped layer 300, thereby reducing the parasitic capacitance between the gate structure and the source-drain doped layer 300.

Referring to FIG. 6, a channel layer structure 240 suspended above the substrate 100 is formed. In a vertical direction (as shown in the Z direction in FIG. 6), the channel layer structure 240 includes one or more spaced channel layers 220.

A channel layer 220 is used as a channel of the semiconductor structure.

In some embodiments, in the process of providing the substrate 100, the bottom layer of the stacked structure is a channel layer 220. Correspondingly, in the process of forming the channel layer structure 240 suspended above the substrate 100, the bottom channel layer 220 is in contact with the isolation layer 210, so the bottom channel layer 220 is isolated from the substrate 100 by the isolation layer 210.

In some embodiments, the process of forming the channel layer structure 240 suspended above the substrate 100 includes: removing the sacrificial layers 230, forming grooves 400 exposing the surfaces of the channel layers 220, where a plurality of spaced channel layers 220 constitute the channel layer structure 240.

The grooves 400 provide a space for the subsequent formation of the gate structure. The grooves 400 expose the surfaces of the channel layers 220 to prepare for the subsequent formation of the repair layer.

In some embodiments, a wet etching process is used to remove the sacrificial layers 230 to form the grooves 400 exposing the surfaces of the channel layers 220.

The process cost of the wet etching process is relatively low, and the operation steps are simple. The wet etching process may also achieve a large etching selectivity ratio, which is beneficial to reduce damage to the surface of the channel layers 220 during the process of removing the sacrificial layers 230.

In some embodiments, during the process of removing the sacrificial layers 230, the grooves 400 also expose the inner sidewalls 500.

The grooves 400 also expose the inner sidewalls 500, so that the gate structure subsequently formed in the grooves 400 is isolated from the source-drain doped layer 300 by the inner sidewalls 500.

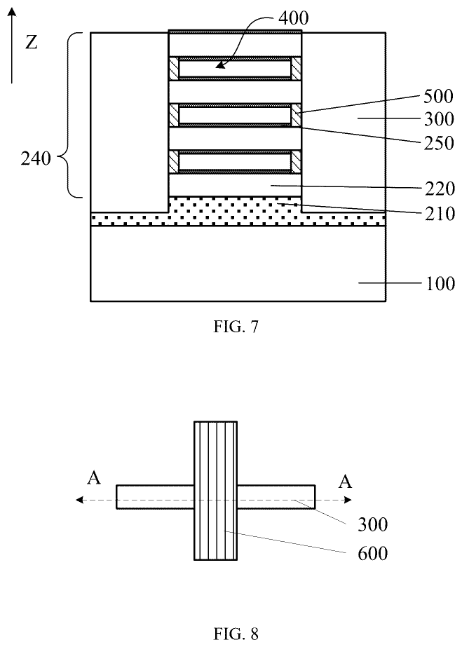

Referring to FIG. 7, the repair layer 250 is formed to cover the surfaces of the channel layers 220.

The repair layer 250 is used to repair the surfaces of the channel layers 220 to obtain a channel surface with better surface quality.

In some embodiments, the repair layer 250 covers the surfaces of the channel layers 220, which is beneficial to ameliorating the defects on the surfaces of the channel layers 220 and obtaining a channel surface with higher surface quality. The subsequently formed gate structure surrounds the channel layers 220 and covers the repair layer 250. The repair layer 250 is used as the channel surface to contact the gate structure, so that the surface quality of the channel surface in contact between the gate structure and the channel layers 220 is improved, which is beneficial to improving the mobility of the channel layer 220, thereby helping improve the working performance of the semiconductor structure.

Accordingly, in the disclosed embodiments, in the process of forming the repair layer 250 covering the surfaces of the channel layers 220, the repair layer 250 is formed on the surfaces of the channel layers 220 through the grooves 400.

In some embodiments, in the process of forming the repair layer 250 covering the surfaces of the channel layers 220, the repair layer 250 covers the upper and lower surfaces of the channel layers 220.

The repair layer 250 covers the surfaces on the upper and lower sides of the channel layers 220, and may repair the exposed surfaces of the channel layers 220, so that each surface (except the upper surface of the top channel layer and the lower surface of the bottom channel layer) of the channel layers 220 has a good surface quality, thereby making each channel surface in contact between the gate structure and the channel layers 220 have a good surface quality. This is beneficial to better improve the mobility of the channel layer 220, and further beneficial to better improve the working performance of the semiconductor structure.

In some embodiments, in the channel layer structure 240, the bottom channel layer 220 contacts the isolation layer 210. Accordingly, in the process of forming the repair layer 250 covering the surfaces of the channel layers 220, the repair layer 250 covers the upper surface of the bottom channel layer 220.

In some embodiments, in the process of providing the substrate 100, the inner sidewalls 500 occupy part of the surfaces of the channel layer 220, and accordingly, in the process of forming the repair layer 250 covering the surfaces of the channel layers 220, the repair layer 250 is formed on the surfaces of the channel layers 220 exposed by the inner sidewalls 500.

In some embodiments, in the process of forming the repair layer 250 covering the surfaces of the channel layers 220, the material of the repair layer 250 includes silicon germanium.

The silicon germanium-covered channel layers 220 serve as the channel surface and may provide good mobility for the channel.

In some embodiments, in the process of forming the repair layer 250 covering the surfaces of the channel layers 220, an epitaxial growth process is used to form the repair layer 250 covering the surfaces of the channel layers 220.

The material of the channel layers 220 is silicon, and the repair layer 250 is silicon germanium. The repair layer 250 may be formed on the surfaces of the channel layers 220 by an epitaxial growth process. The formation process is simple and does not require an additional etching process, thereby minimizing damage to the structure.

In addition, the epitaxial growth process may better control the process parameters, and the process controllability is high, and it is easy to obtain a more precise film thickness of the repair layer 250. The epitaxial growth process makes it easy to form a film layer with fewer impurities, so that the film quality of the repair layer 250 is higher, which is further beneficial to ameliorating the defects on the surfaces of the channel layers 220 and obtaining a channel surface with higher surface quality. Correspondingly, the surface quality of the channel surface in contact between the gate structure and the channel layers 220 is improved. This is further beneficial to improve the mobility of the channel layer 220, and thus is more beneficial to improve the working performance of the semiconductor structure.

It should be noted that, in the present disclosure, in the process of forming the repair layer 250 covering the surfaces of the channel layers 220, the thickness of the repair layer 250 should not be too large. If the thickness of the repair layer 250 is too large, it is easy for the repair layer 250 to occupy too much space between the adjacent channel layers 220 in the vertical direction (i.e., the space of a groove 400), resulting in insufficient space for forming the gate structure between the adjacent channel layers 220 in the vertical direction, which is easy to cause difficulties in the formation of the gate structure, and also affects the quality of the formed gate structure, thereby affecting the working performance of the semiconductor structure. For this reason, in the present disclosure, in the process of forming the repair layer 250 covering the surfaces of the channel layers 220, the thickness of the repair layer 250 is less than or equal to 2 nm.

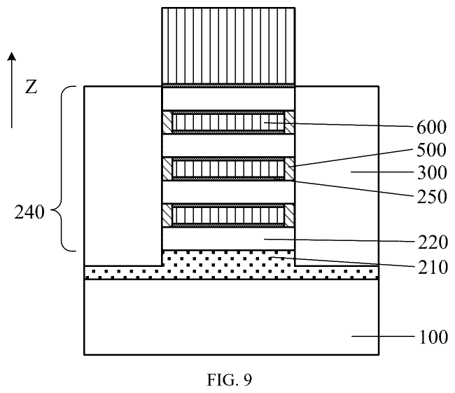

Referring to FIGS. 8 and 9, FIG. 9 is a cross-sectional view of FIG. 8 along the AA direction. A gate structure 600 is formed on the substrate 100 across the channel layer structure 240, and the gate structure 600 surrounds the channel layers 220 along an extension direction of the gate structure 600 and covers the repair layer 250.

The gate structure 600 is used to control the turning on and off of the channels of the transistor.

The gate structure 600 surrounds and covers the channel layers 220, so the top, bottom, and sidewalls of the channel layers 220 may all serve as channels, increasing the area of the channel layers 220 used as a channel, thereby increasing the operating current of the semiconductor structure.

In some embodiments, the gate structure 600 includes a gate dielectric layer surrounding a channel layer 220 along the extension direction of the gate structure 600, and a gate electrode layer located on the gate dielectric layer.

The gate dielectric layer is used to isolate the gate electrode layer from a channel layer 220, or the gate electrode layer from the substrate 100.

The material of the gate dielectric layer includes one or more of HfO₂, ZrO₂, HfSiO, HfSiON, HfTaO, HfTIO, HfZrO, Al₂O₃, SiO₂, La2O3, etc. In some embodiments, the gate dielectric layer is a high-k gate dielectric layer, and the material of the high-k gate dielectric layer includes a high-k dielectric material. The high-k dielectric material refers to a dielectric material having a relative dielectric constant greater than the relative dielectric constant of silicon oxide. Specifically, the material of the high-k gate dielectric layer includes HfO₂, ZrO₂, HfSiO, HfSiON, HfTaO, HfTiO, HfZrO, Al₂O₃, etc.

It should be noted that the gate dielectric layer may further include a gate oxide layer, and the gate oxide layer is located between the high-k gate dielectric layer and a channel layer 220. Specifically, the material of the gate oxide layer may be silicon oxide.

In some embodiments, the gate structure 600 is a metal gate structure, and therefore the material of the gate electrode layer includes one or more of TiN, TaN, Ta, Ti, TiAl, W, Al, TiSiN, TiAlC, etc.

Specifically, the gate electrode layer includes a work function layer (not shown) and an electrode layer (not shown) located on the work function layer, where the work function layer is used to adjust the threshold voltage of the transistor, and the electrode layer is used to lead out the electrical properties of the metal gate structure.

In some embodiments, the gate electrode layer may only include a work function layer.

In some embodiments, according to process requirements, the gate structure may also be a polysilicon gate structure.

Specifically, in the present disclosure, in the process of forming the gate structure 600 across the channel layer structure 240 on the substrate 100, the gate structure 600 fills the grooves 400 and covers the repair layer 250.

The gate structure 600 fills the grooves 400 and covers the repair layer 250, so that the top, bottom, and side walls of a channel layer 220 may all serve as channels, increasing the area of a channel layer 220 used as a channel, thereby increasing the working current of the semiconductor structure. The covered repair layer 250 as a channel surface is beneficial to increasing channel mobility and improving the working performance of the semiconductor structure.

Compared with the existing technologies, the technical solutions of the embodiments of the present disclosure have the following advantages.

In the semiconductor structure provided by the embodiments of the present disclosure, the repair layer covers the surfaces of the channel layers, the gate structure is located on the substrate and spans the channel layer structure, and the gate structure surrounds the channel layers along the extension direction of the gate structure and covers the repair layer. In the embodiments of the present disclosure, the repair layer covers the surfaces of the channel layers, which is beneficial to ameliorating the defects on the surfaces of the channel layers and obtaining a channel surface with higher surface quality. The gate structure surrounds the channel layers and covers the repair layer. The repair layer is used as the channel surface to contact the gate structure, so that the surface quality of the channel surface in contact between the gate structure and the channel layers is improved, which is beneficial to improving the mobility of the channel layers, thereby improving the working performance of the semiconductor structure.

In the formation method provided in the embodiments of the present disclosure, a repair layer covering the surfaces of the channel layers is formed, a gate structure spanning the channel layer structure is formed on the substrate, and the gate structure surrounds the channel layers along the extension direction of the gate structure and covers the repair layer. In the embodiments of the present disclosure, the repair layer covers the surfaces of the channel layers, which is beneficial to ameliorating the defects on the surfaces of the channel layers and obtaining a channel surface with higher surface quality. The gate structure surrounds the channel layers and covers the repair layer, and the repair layer is used as the channel surface to contact the gate structure, so that the surface quality of the channel surface in contact between the gate structure and the channel layers is improved, which is beneficial to improving the mobility of the channel layers, thereby facilitating improving the working performance of the semiconductor structure.

It should be noted that, in this disclosure, relational terms such as “first” and “second” are only used to distinguish one entity or operation from another entity or operation, and do not necessarily require or imply any such actual relationship or order between these entities or operations. Moreover, the terms “include”, “comprise” or any other variants thereof are intended to cover non-exclusive inclusion, so that a process, method, article, or device including a series of elements includes not only those elements, but also other elements not explicitly listed, or also includes elements inherent to such process, method, article or device. In the absence of further restrictions, the elements defined by the sentence “comprise a . . . ” do not exclude the existence of other identical elements in the process, method, article, or device including the elements.

The above description is only a specific embodiment of the present disclosure, so that those skilled in the art can understand or implement the present disclosure. Various modifications to these embodiments will be apparent to those skilled in the art, and the general principles defined herein may be implemented in other embodiments without departing from the spirit or scope of the present disclosure. Therefore, the present disclosure will not be limited to the embodiments described herein, but will conform to the widest scope consistent with the principles and novel features disclosed herein.

What is claimed is:

1. A semiconductor structure, comprising:
a substrate;
a channel layer structure suspended above the substrate, wherein, in a vertical direction, the channel layer structure includes one or more spaced channel layers;
a repair layer, covering surfaces of the channel layers; and
a gate structure located on the substrate and across the channel layer structure, wherein the gate structure surrounds the channel layers along an extension direction of the gate structure and covers the repair layer.

2. The semiconductor structure according to claim 1, wherein the repair layer covers upper and lower surfaces of the channel layers.

3. The semiconductor structure according to claim 2, further comprising an isolation layer located between the channel layer structure and the substrate, wherein:
in the channel layer structure, a bottom channel layer is in contact with the isolation layer; and
the repair layer covers an upper surface of the bottom channel layer.

4. The semiconductor structure according to claim 3, wherein:
the semiconductor structure further includes a source-drain doped layer, located on the substrate at both sides of the gate structure, and in an extension direction of the channel layer structure, the source-drain doped layer is in contact with side surfaces of the channel layer structure; and
the isolation layer is also located between the source-drain doped layer and the substrate.

5. The semiconductor structure according to claim 4, further comprising inner sidewalls located between adjacent channel layers and between the gate structure and the source-drain doped layer,
wherein the repair layer is disposed on surfaces of the channel layers exposed by the inner sidewalls.

6. The semiconductor structure according to claim 1, wherein a material of the repair layer includes silicon germanium.

7. The semiconductor structure according to claim 1, wherein a thickness of the repair layer is less than or equal to 2 nm.

8. The semiconductor structure according to claim 1, wherein a material of the channel layers includes silicon, germanium, silicon germanium, or a group III-V semiconductor material.

9. The semiconductor structure according to claim 1, wherein the gate structure includes a gate dielectric layer surrounding a channel layer along the extension direction of the gate structure and a gate electrode layer located on the gate dielectric layer, wherein the gate electrode layer includes a work function layer and an electrode layer located on the work function layer.

10. A method of forming a semiconductor structure, comprising:
providing a substrate;
forming a channel layer structure suspended above the substrate, wherein the channel layer structure includes one or more spaced channel layers in a vertical direction;
forming a repair layer covering surfaces of the channel layers; and
forming a gate structure on the substrate and across the channel layer structure, wherein the gate structure surrounds the channel layers along an extension direction of the gate structure and covers the repair layer.

11. The method according to claim 10, wherein, in a process of forming the repair layer covering the surfaces of the channel layers, the repair layer covers upper and lower surfaces of the channel layers.

12. The method according to claim 10, wherein:
in a process of providing the substrate, an isolation layer is formed on the substrate;
in a process of forming the channel layer structure suspended above the substrate, a bottom channel layer is in contact with the isolation layer; and
in a process of forming the repair layer covering the surfaces of the channel layers, the repair layer covers a upper surface of the bottom channel layer.

13. The method according to claim 12, wherein:
in the process of providing the substrate, a stacked structure is formed on the isolation layer, the stacked structure including alternately stacked channel layers and sacrificial layers, wherein a bottom layer of the stacked structure is a channel layer;
in the process of forming the channel layer structure suspended above the substrate, the sacrificial layers are removed to form grooves exposing the surfaces of the channel layers, wherein a plurality of spaced channel layers constitute the channel layer structure; and
in the process of forming the repair layer covering the surfaces of the channel layers, the repair layer is formed on the surfaces of the channel layers through the grooves.

14. The method according to claim 13, wherein in the process of providing the substrate, a source-drain doped layer is formed on the isolation layer on both sides of the stacked structure along an extension direction of the stacked structure, and the source-drain doped layer is in contact with side surfaces of the stacked structure.

15. The method according to claim 14, wherein:
in the process of providing the substrate, inner sidewalls are further formed between the sacrificial layers and the source-drain doped layer;
in a process of removing the sacrificial layers, the grooves also expose the inner sidewalls; and
in the process of forming the repair layer covering the surfaces of the channel layers, the repair layer is formed on surfaces of the channel layers exposed by the inner sidewalls.

16. The method according to claim 13, wherein in the process of forming the gate structure across the channel layer structure on the substrate, the gate structure fills the grooves and covers the repair layer.

17. The method according to claim 10, wherein an epitaxial growth process is used to form the repair layer covering the surfaces of the channel layers.

18. The method according to claim 10, wherein, in the process of forming the repair layer covering the surfaces of the channel layers, a material of the repair layer includes silicon germanium.

19. The method according to claim 10, wherein, in the process of forming the repair layer covering the surfaces of the channel layers, a thickness of the repair layer is less than or equal to 2 nm.

20. The method according to claim 10, wherein, in the process of forming the channel layer structure suspended above the substrate, a material of the channel layers includes silicon, germanium, silicon germanium, or a group III-V semiconductor material.
